(19) United States
(12) Patent Application Publication
(10) Pub. No.: US 2026/0075766 A1
(43) Pub. Date: Mar. 12, 2026

(54) STEP-SHAPED AIR MOVERS AND HEAT-REJECTING MEDIA

(71) Applicant: Dell Products L.P., Round Rock, TX (US)

(72) Inventors: Jay M. ZILL, Round Rock, TX (US); Qinghong HE, Austin, TX (US)

(73) Assignee: Dell Products L.P., Round Rock, TX (US)

(21) Appl. No.: 18/882,261

(22) Filed: Sep. 11, 2024

(51) Int. Cl. H05K 7/20; G06F 1/20

(52) U.S. Cl. CPC H05K 7/20336; G06F 1/203; H05K 7/20145

(57) ABSTRACT

A method may include thermally coupling heat-rejecting media to an information handling resource and arranging the heat-rejecting media to have a portion of the heat-rejecting media downstream of airflow of exhausts of a first air mover and a second air mover, wherein the portion comprises: a first region downstream of an exhaust of the first air mover and having a first depth in a direction substantially parallel to a direction of airflow from the exhaust of the first air mover and a second region downstream of an exhaust of the second air mover and having a second depth in the direction substantially parallel to the direction of airflow from the exhaust of the first air mover, wherein the second depth is substantially smaller than the first depth.

### TECHNICAL FIELD

The present disclosure relates in general to information handling systems, and more particularly to cooling of information handling system components using heat-rejecting media and a plurality of air movers, including air movers and heat-rejecting media sized and shaped to maximize heat transfer.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

As processors, graphics cards, random access memory (RAM) and other components in information handling systems have increased in clock speed and power consumption, the amount of heat produced by such components as a side-effect of normal operation has also increased. Often, the temperatures of these components need to be kept within a reasonable range to prevent overheating, instability, malfunction and damage leading to a shortened component lifespan. Accordingly, air movers (e.g., cooling fans and blowers) have often been used in information handling systems to cool information handling systems and their components.

Further, heat-rejecting media such as heat pipes, heat spreaders, and heat sinks are often thermally coupled to heat-generating devices of information handling systems and placed in the airflow path of an air mover, to also aid in cooling of an information handling system and its components. Such heat-rejecting media may be thermally-coupled to one or more heat-generating devices of an information handling system, and configured to transfer heat from such heat-generating devices. Further, such heat-rejecting media may include surfaces located within the airflow of air movers, so that heat may further be transferred from heat-rejecting media to the cooling airflow.

### SUMMARY

In accordance with the teachings of the present disclosure, the disadvantages and problems associated with traditional approaches to cooling information handling system components may be substantially reduced or eliminated.

In accordance with embodiments of the present disclosure, an information handling system may include a housing, an information handling resource housed within the housing, a first air mover, a second air mover, and heat-rejecting media thermally coupled to the information handling resource and having a portion of the heat-rejecting media downstream of airflow of exhausts of the first air mover and the second air mover. The portion may comprise a first region downstream of an exhaust of the first air mover and having a first depth in a direction substantially parallel to a direction of airflow from the exhaust of the first air mover and a second region downstream of an exhaust of the second air mover and having a second depth in the direction substantially parallel to the direction of airflow from the exhaust of the first air mover, wherein the second depth is substantially smaller than the first depth.

In accordance with these and other embodiments of the present disclosure, heat-rejecting media configured to thermally couple to an information handling resource and configured to have a portion of the heat-rejecting media downstream of airflow of exhausts of a first air mover and a second air mover, wherein the portion comprises a first region configured to be downstream of an exhaust of the first air mover and having a first depth in a direction substantially parallel to a direction of airflow from the exhaust of the first air mover and a second region configured to be downstream of an exhaust of the second air mover and having a second depth in the direction substantially parallel to the direction of airflow from the exhaust of the first air mover, wherein the second depth is substantially smaller than the first depth.

In accordance with these and other embodiments of the present disclosure, a method may include thermally coupling heat-rejecting media to an information handling resource and arranging the heat-rejecting media to have a portion of the heat-rejecting media downstream of airflow of exhausts of a first air mover and a second air mover, wherein the portion comprises: a first region downstream of an exhaust of the first air mover and having a first depth in a direction substantially parallel to a direction of airflow from the exhaust of the first air mover and a second region downstream of an exhaust of the second air mover and having a second depth in the direction substantially parallel to the direction of airflow from the exhaust of the first air mover, wherein the second depth is substantially smaller than the first depth.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a block diagram of selected components of an example information handling system, in accordance with embodiments of the present disclosure;

FIG. 2 illustrates a plan view of selected components of an example information handling system, in accordance with embodiments of the present disclosure;

FIG. 3 illustrates a plan view of selected components of another example information handling system, in accordance with embodiments of the present disclosure; and

FIG. 4 illustrates a plan view of selected components of yet another example information handling system, in accordance with embodiments of the present disclosure.

### DETAILED DESCRIPTION

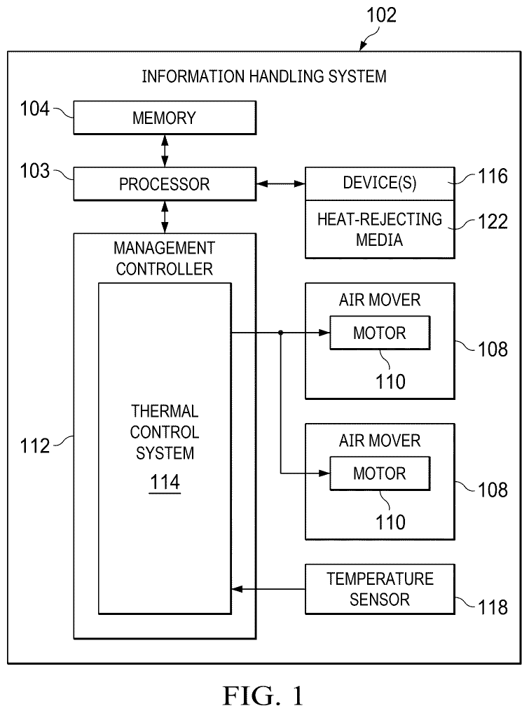

Preferred embodiments and their advantages are best understood by reference to FIGS. 1 through 4, wherein like numbers are used to indicate like and corresponding parts.

For the purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a PDA, a consumer electronic device, a network storage device, or any other suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, computer-readable media may include any instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory; as well as communications media such as wires, optical fibers, microwaves, radio waves, and other electromagnetic and/or optical carriers; and/or any combination of the foregoing.

For the purposes of this disclosure, information handling resources may broadly refer to any component system, device or apparatus of an information handling system, including without limitation processors, buses, memories, I/O devices and/or interfaces, storage resources, network interfaces, motherboards, integrated circuit packages; electro-mechanical devices (e.g., air movers), displays, and power supplies.

FIG. 1 illustrates a block diagram of selected components of an example information handling system 102, in accordance with embodiments of the present disclosure. In some embodiments, information handling system 102 may comprise a server chassis configured to house a plurality of servers or “blades.” In other embodiments, information handling system 102 may comprise a personal computer (e.g., a desktop computer, laptop computer, mobile computer, and/or notebook computer). In yet other embodiments, information handling system 102 may comprise a storage enclosure configured to house a plurality of physical disk drives and/or other computer-readable media for storing data. As shown in FIG. 1, information handling system 102 may comprise a processor 103, a memory 104 communicatively coupled to processor 103, a plurality of air movers 108, a management controller 112, one or more devices 116 communicatively coupled to processor 103, a temperature sensor 118, and heat-rejecting media 122 thermally coupled to device(s) 116.

Processor 103 may comprise any system, device, or apparatus operable to interpret and/or execute program instructions and/or process data, and may include, without limitation a microprocessor, microcontroller, digital signal processor (DSP), application specific integrated circuit (ASIC), or any other digital or analog circuitry configured to interpret and/or execute program instructions and/or process data. In some embodiments, processor 103 may interpret and/or execute program instructions and/or process data stored in memory 104 and/or another component of information handling system 102.

Memory 104 may be communicatively coupled to processor 103 and may comprise any system, device, or apparatus operable to retain program instructions or data for a period of time. Memory 104 may comprise random access memory (RAM), electrically erasable programmable read-only memory (EEPROM), a PCMCIA card, flash memory, magnetic storage, opto-magnetic storage, or any suitable selection and/or array of volatile or non-volatile memory that retains data after power to information handling system 102 is turned off.

An air mover 108 may include any mechanical or electro-mechanical system, apparatus, or device operable to move air and/or other gases in order to cool information handling resources of information handling system 102. In some embodiments, an air mover 108 may comprise a fan (e.g., a rotating arrangement of vanes or blades which act on the air). In other embodiments, an air mover 108 may comprise a blower (e.g., a centrifugal fan that employs rotating impellers to accelerate air received at its intake and change the direction of the airflow). In these and other embodiments, rotating and other moving components of an air mover 108 may be driven by a motor 110. The rotational speed of motor 110 may be controlled by an air mover control signal (e.g., a pulse-width modulation signal) communicated from thermal control system 114 of management controller 112. In operation, an air mover 108 may cool information handling resources of information handling system 102 by drawing cool air into an enclosure housing the information handling resources from outside the chassis, expelling warm air from inside the enclosure to the outside of such enclosure, and/or moving air across one or more heat sinks (not explicitly shown) internal to the enclosure to cool one or more information handling resources.

Management controller 112 may comprise any system, device, or apparatus configured to facilitate management and/or control of information handling system 102 and/or one or more of its component information handling resources. Management controller 112 may be configured to issue commands and/or other signals to manage and/or control information handling system 102 and/or its information handling resources. Management controller 112 may comprise a microprocessor, microcontroller, DSP, ASIC, field programmable gate array (“FPGA”), EEPROM, or any combination thereof. Management controller 112 also may be configured to provide out-of-band management facilities for management of information handling system 102. Such management may be made by management controller 112 even if information handling system 102 is powered off or powered to a standby state. In certain embodiments, management controller 112 may include or may be an integral part of a baseboard management controller (BMC), a remote access controller (e.g., a Dell Remote Access Controller or Integrated Dell Remote Access Controller), or an enclosure controller. In other embodiments, management controller 112 may include or may be an integral part of a chassis management controller (CMC).

As shown in FIG. 1, management controller 112 may include a thermal control system 114. Thermal control system 114 may include any system, device, or apparatus configured to receive one or more signals indicative of one or more temperatures within information handling system 102 (e.g., one or more signals from one or more temperature sensors 118) and based on such one or more signals, calculate an air mover driving signal (e.g., a pulse-width modulation signal) to maintain an appropriate level of cooling, increase cooling, or decrease cooling, as appropriate, and communicate such air mover driving signal to air movers 108. Thermal control for air movers 108 by thermal control system 114 may be performed in any suitable manner, for example, as described in U.S. Pat. No. 10,146,190 entitled “Systems and Methods for Providing Controller Response Stability in a Closed-Loop System.”

In addition, thermal control system 114 may also be configured to maintain acoustic limits and/or maintain acoustic preferences for sound generated by air movers 108, for example, as described in U.S. patent application Ser. No. 16/852,118, filed Apr. 17, 2020, and entitled “Systems and Methods for Acoustic Limits of Thermal Control System in an Information Handling System,” which is incorporated by reference herein in its entirety.

In some embodiments, thermal control system 114 may include a program of instructions (e.g., software, firmware) configured to, when executed by a processor or controller integral to management controller 112, carry out the functionality of thermal control system 114.

A device 116 may comprise any component information handling system of information handling system 102, including without limitation processors, buses, memories, I/O devices and/or interfaces, storage resources, network interfaces, motherboards, integrated circuit packages; electro-mechanical devices, displays, and power supplies.

Temperature sensor 118 may comprise any system, device, or apparatus (e.g., a thermometer, thermistor, etc.) configured to communicate a signal to thermal control system 114 indicative of a temperature within information handling system 102.

Heat-rejecting media 122 may include any system, device, or apparatus configured to transfer heat from an information handling resource (e.g., device(s) 116, as shown in FIG. 1), thus reducing a temperature of the information handling resource. For example, heat-rejecting media 122 may include one or more solids thermally coupled to the information handling resource (e.g., heat pipe, heat spreader, heatsink, finstack, vapor chamber, etc.) such that heat generated by the information handling resource is transferred from the information handling resource.

Further, heat-rejecting media 122 may be arranged to be located within the airflow path of airflow generated by air movers 108, such that heat transferred to heat-rejecting media 122 from device 116 may further be transferred to such airflow. Although, for purposes of clarity and exposition, heat-rejecting media 122 is shown as being thermally coupled to device(s) 116, it is understood that heat-rejecting media 122 may also be thermally coupled to other information handling resources (e.g., processor 103 and/or memory 104) of information handling system 102 in addition to or in lieu of being thermally coupled to device 116.

In addition to processor 103, memory 104, air movers 108, management controller 112, device(s) 116, temperature sensor 118, and heat-rejecting media 122, information handling system 102 may include one or more other information handling resources. In addition, for the sake of clarity and exposition of the present disclosure, FIG. 1 depicts two air movers 108 and one temperature sensor 118. In embodiments of the present disclosure, information handling system 102 may include any number of air movers 108 and temperature sensors 118.

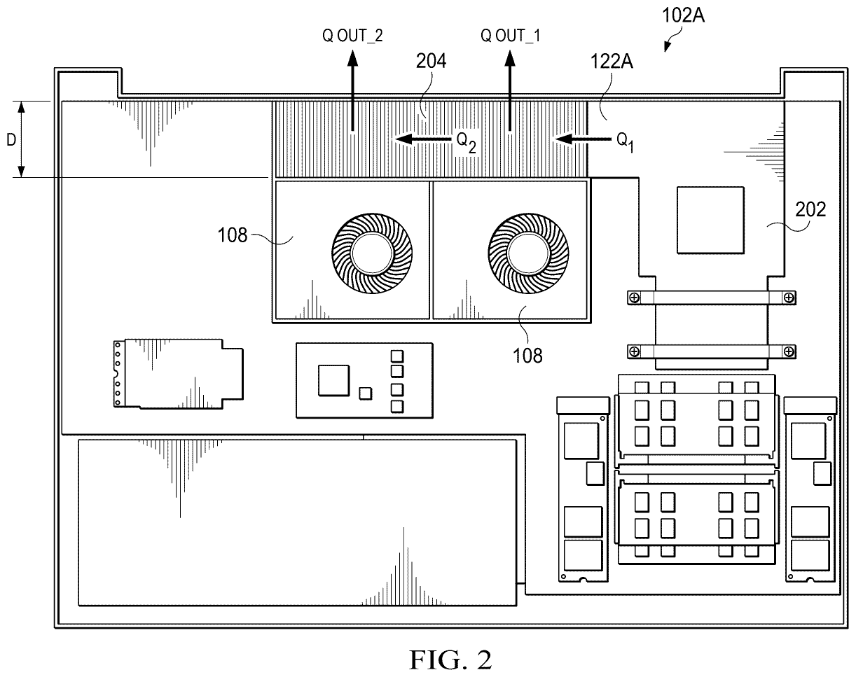

FIG. 2 illustrates a plan view of selected components of an example information handling system 102A, in accordance with embodiments of the present disclosure. Information handling system 102A depicted in FIG. 2 may be used to implement information handling system 102 depicted in FIG. 1. For purposes of clarity and exposition, FIG. 2 depicts information handling system 102A with a portion of its housing (e.g., a “D-cover”) removed.

As shown in FIG. 2, information handling system 102A may include (in addition to those components shown in FIG. 1 and not also explicitly shown in FIG. 2) heat-rejecting media 122A comprising a vapor chamber 202 and a fin stack 204 thermally coupled to vapor chamber 202, which may implement heat-rejecting media 122 of FIG. 1. Vapor chamber 202 may be thermally coupled to processor 103, device(s) 116, and/or other heat-generating components of information handling system 102A. It is also noted that vapor chamber 202 may extend to portions of information handling system 102A obscured in FIG. 2 by fin stack 204 (e.g., fin stack 204 may be on “top” of vapor chamber 202 from the perspective shown in FIG. 2).

Information handling system 102A may also include air movers 108 arranged side-by-side with one another and arranged relative to fin stack 204, such that air exhausting from air movers 108 flows proximate to surfaces of a plurality of fins integral to fin stack 204.

In operation, heat generated by heat-generating components of information handling system 102A may be transferred to vapor chamber 202, which may in turn be transferred to fin stack 204. Such heat may then be transferred to air flowing proximate to fins of fin stack 204 and exhausted from information handling system 102A, with the result of cooling such heat-generating components of information handling system 102A.

A maximum heat transfer capacity Q_{MAX} of vapor chamber 202 in the region of fin stack 204 may be a function of its depth D, assuming a fixed thickness and length. The larger depth D, the higher maximum heat transfer capacity Q_{MAX} that vapor chamber 202 may achieve. Other the other hand, if a heat transfer requirement for vapor chamber 202 is smaller, so too is the required depth D of vapor chamber 202.

In the arrangement shown in FIG. 2, the heat transfer rate within vapor chamber 202 in the region of fin stack 204 may not be constant. To illustrate, of heat Q₁ transferred into the vapor chamber 202 region of fin stack 204, a heat Q_{OUT_1} may exhaust from information handling system 102A downstream of the airflow of the right-most air mover 108B, with a heat Q₂ transferred to the region of vapor chamber 202 closer to the left-most air mover 108A (which may be approximately equal to heat Q_{OUT_2} exhausting from information handling system 102A downstream of the airflow of the left-most air mover 108A). Accordingly given that exhausted heat Q_{OUT_1} is positive and nonzero, heat Q₂ transferred by the portion of vapor chamber 202 in the fin stack region downstream of the left-most air mover 108A will be smaller than heat Q₁ transferred by the portion of vapor chamber 202 in the fin stack region downstream of the right-most air mover 108B.

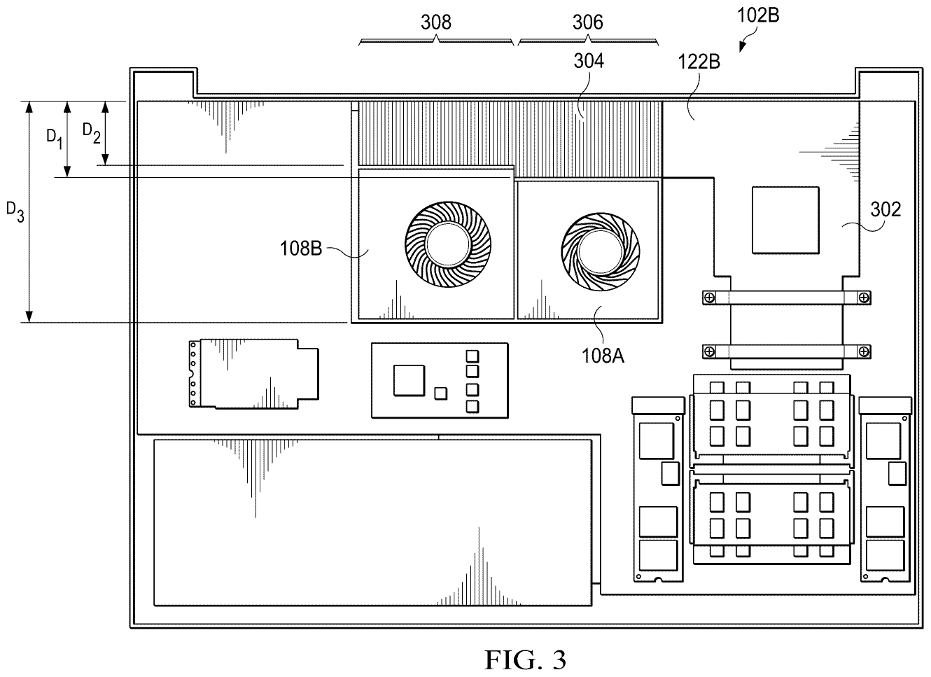

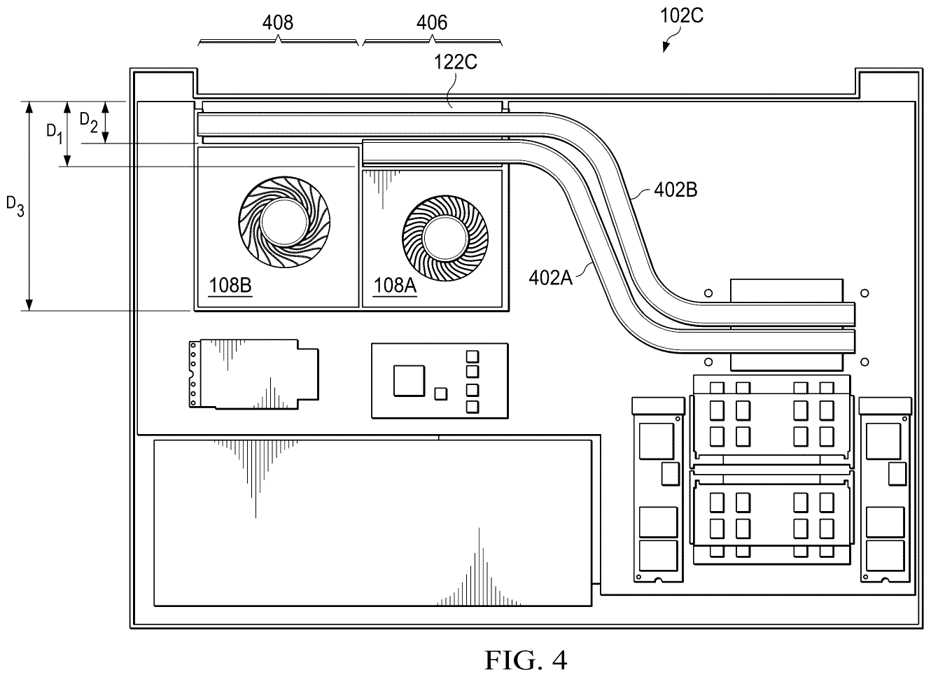

As a result of this fact, the depth of the region of vapor chamber 202 having the smaller heat transfer requirement may be smaller than the depth of the region of vapor chamber 202 having the larger heat transfer requirement, as described in greater detail below with respect to FIGS. 3 and 4.

FIG. 3 illustrates a plan view of selected components of an example information handling system 102B, in accordance with embodiments of the present disclosure. Information handling system 102B depicted in FIG. 3 may be used to implement information handling system 102 depicted in FIG. 1. For purposes of clarity and exposition, FIG. 3 depicts information handling system 102B with a portion of its housing (e.g., a “D-cover”) removed.

As shown in FIG. 3, information handling system 102B may include (in addition to those components shown in FIG. 1 and not also explicitly shown in FIG. 3) heat-rejecting media 122B comprising a vapor chamber 302 and a fin stack 304 thermally coupled to vapor chamber 302, which may implement heat-rejecting media 122 of FIG. 1. Vapor chamber 302 may be thermally coupled to processor 103, device(s) 116, and/or other heat-generating components of information handling system 102B. It is also noted that vapor chamber 302 may extend to portions of information handling system 102B obscured in FIG. 3 by fin stack 304 (e.g., fin stack 304 may be on “top” of vapor chamber 302 from the perspective shown in FIG. 3).

Further, heat-rejecting media 122B may have a first portion 306 having a depth D₁ for vapor chamber 302 in a region downstream of the exhaust of an air mover 108A and a second portion 308 having a depth D₂ for vapor chamber 302 downstream of the exhaust of an air mover 108B, with depth D₂ being smaller than depth D₁, wherein such depths D₁ and D₂ are substantially parallel to the air flow exhausting from air movers 108A and 108B.

For reasons described above, second portion 308 of heat-rejecting media 122B may be required to transfer less heat than first portion 306 of heat-rejecting media 122B, and thus, depth D₂ may be made smaller than depth D₁ without negatively affecting the heat transfer capabilities of the overall heat-rejecting media 122B. Due to such smaller depth of second portion 308 as compared to that of information handling system 102A shown in FIG. 2, information handling system 102B may have space for other components not present in information handling system 102A. For example, with the reduction in size of heat-rejecting media 122B as compared to heat-rejecting media 122A of information handling system 102A, one of air movers 108 may be increased in size as compared to information handling system 102A.

Accordingly, information handling system 102A may include a first air mover 108A (e.g., in lieu of right-most air mover 108 of FIG. 2) and a second air mover 108B (e.g., in lieu of left-most air mover 108 of FIG. 2), wherein second air mover 108B may be larger in at least one dimension (e.g., in a depth parallel to depths D₁ and D₂) as compared to first air mover 108A. Further, air movers 108A and 108B and regions 306 and 308 of heat-rejecting media 122B may be arranged such that a combined depth of air mover 108A and region 306 (e.g., in a direction substantially parallel to airflow exhausting from air mover 108A) and a combined depth of air mover 108B and region 308 (e.g., in a direction substantially parallel to airflow exhausting from air mover 108B) are a substantially equal depth D₃. Air movers 108A and 108B may be arranged side-by-side with one another and arranged relative to fin stack 304, such that air exhausting from air movers 108A and 108B flows proximate to surfaces of a plurality of fins integral to fin stack 304.

Accordingly, while the cooling system of information handling system 102B may take the same physical footprint as information handling system 102A, information handling system 102B has an increased size of at least one air mover 108 (e.g., air mover 108B) as compared to information handling system 102A, allowing for increased airflow and better cooling within information handling system 102B as compared to information handling system 102A.

While FIG. 3 depicts a particular type of heat-rejecting media 122B, it is understood that the approaches described above with respect to FIG. 3 may also be used in connection with other types of heat-rejecting media, such as that described below with respect to FIG. 4, as an example.

FIG. 4 illustrates a plan view of selected components of an example information handling system 102C, in accordance with embodiments of the present disclosure. Information handling system 102C depicted in FIG. 4 may be used to implement information handling system 102 depicted in FIG. 1. For purposes of clarity and exposition, FIG. 4 depicts information handling system 102C with a portion of its housing (e.g., a “D-cover”) removed.

Information handling system 102C shown in FIG. 4 may be similar in many respects to information handling system 102B shown in FIG. 3. Accordingly, only certain differences between information handling system 102B and information handling system 102C are described below.

In particular, information handling system 102C may include heat-rejecting media 122C in lieu of heat-rejecting media 122B. In turn, heat-rejecting media 122C may include heat pipes 402A and 402B in lieu of vapor chamber 302, with a first region 406 and a second region 408 analogous to first region 306 and second region 308, respectively. First region 406 may include portions of heat pipes 402A and 402B within the airflow exhaust path of air mover 108A while second region 408 may include a portion of heat pipe 402B within the airflow exhaust path of air mover 108B.

Similar to FIG. 3, as shown in FIG. 4, air movers 108A and 108B and regions 406 and 408 of heat-rejecting media 122C may be arranged such that a combined depth of air mover 108A and region 406 (e.g., in a direction substantially parallel to airflow exhausting from air mover 108A) and a combined depth of air mover 108B and region 408 (e.g., in a direction substantially parallel to airflow exhausting from air mover 108B) are a substantially equal depth D₃.

Although the foregoing contemplates heat-rejecting media with two different depths near the exhaust of two air movers, it is understood that in systems with three or more air movers, heat-rejecting media may have three or more different depths near the exhaust of the three or more air movers, in accordance with the systems and methods disclosed herein.

While the terms “top,” “bottom,” “front,” “back,” and “side” are used for purposes of exposition and clarity, such terms are not intended to limit any of the components disclosed herein to a particular orientation or configuration.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

What is claimed is:

1. An information handling system comprising:
a housing;
an information handling resource housed within the housing;
a first air mover;
a second air mover; and
heat-rejecting media thermally coupled to the information handling resource and having a portion of the heat-rejecting media downstream of airflow of exhausts of the first air mover and the second air mover, wherein the portion comprises:
a first region downstream of an exhaust of the first air mover and having a first depth in a direction substantially parallel to a direction of airflow from the exhaust of the first air mover; and
a second region downstream of an exhaust of the second air mover and having a second depth in the direction substantially parallel to the direction of airflow from the exhaust of the first air mover, wherein the second depth is substantially smaller than the first depth.

2. The information handling system of claim 1, wherein a first dimension of the first air mover in the direction substantially parallel to the direction of airflow from the exhaust of the first air mover is smaller than a second dimension of the second air mover in the direction substantially parallel to the direction of airflow from the exhaust of the first air mover.

3. The information handling system of claim 2, wherein a first combined depth of the first depth and the first dimension is approximately equal to a second combined depth of the second depth and the second dimension.

4. The information handling system of claim 1, wherein the heat-rejecting media comprises, within the portion, at least a part of a vapor chamber thermally coupled to the information handling resource and a fin stack thermally coupled to the vapor chamber such that the vapor chamber and the fin stack are downstream of the exhausts of the airflow of the first air mover and the second air mover.

5. The information handling system of claim 1, wherein the heat-rejecting media further comprises:
a first heat pipe thermally coupled to the information handling resource; and
a second heat pipe thermally coupled to the information handling resource;
wherein:
the first region includes a first part of the first heat pipe and a first part of the second heat pipe; and
the second region includes a second part of the first heat pipe and excludes the second heat pipe.

6. Heat-rejecting media configured to thermally couple to an information handling resource and configured to have a portion of the heat-rejecting media downstream of airflow of exhausts of a first air mover and a second air mover, wherein the portion comprises:
a first region configured to be downstream of an exhaust of the first air mover and having a first depth in a direction substantially parallel to a direction of airflow from the exhaust of the first air mover; and
a second region configured to be downstream of an exhaust of the second air mover and having a second depth in the direction substantially parallel to the direction of airflow from the exhaust of the first air mover, wherein the second depth is substantially smaller than the first depth.

7. The heat-rejecting media of claim 6, further comprising, within the portion, at least a part of a vapor chamber thermally coupled to the information handling resource and a fin stack thermally coupled to the vapor chamber such that the vapor chamber and the fin stack are downstream of the exhausts of the airflow of the first air mover and the second air mover.

8. The heat-rejecting media of claim 6, wherein the heat-rejecting media further comprises:
a first heat pipe thermally coupled to the information handling resource; and
a second heat pipe thermally coupled to the information handling resource;
wherein:
the first region includes a first part of the first heat pipe and a first part of the second heat pipe; and
the second region includes a second part of the first heat pipe and excludes the second heat pipe.

9. A method comprising:
thermally coupling heat-rejecting media to an information handling resource; and
arranging the heat-rejecting media to have a portion of the heat-rejecting media downstream of airflow of exhausts of a first air mover and a second air mover, wherein the portion comprises:
a first region downstream of an exhaust of the first air mover and having a first depth in a direction substantially parallel to a direction of airflow from the exhaust of the first air mover; and
a second region downstream of an exhaust of the second air mover and having a second depth in the direction substantially parallel to the direction of airflow from the exhaust of the first air mover, wherein the second depth is substantially smaller than the first depth.

10. The method of claim 9, further comprising arranging the heat-rejecting media such that a first dimension of the first air mover in the direction substantially parallel to the direction of airflow from the exhaust of the first air mover is smaller than a second dimension of the second air mover in the direction substantially parallel to the direction of airflow from the exhaust of the first air mover.

11. The method of claim 10, further comprising arranging the heat-rejecting media such that a first combined depth of the first depth and the first dimension is approximately equal to a second combined depth of the second depth and the second dimension.

12. The information handling system of claim 9, wherein the heat-rejecting media comprises, within the portion, at least a part of a vapor chamber thermally coupled to the information handling resource and a fin stack thermally coupled to the vapor chamber such that the vapor chamber and the fin stack are downstream of the exhausts of the airflow of the first air mover and the second air mover.

13. The information handling system of claim 9, wherein the heat-rejecting media further comprises:
a first heat pipe thermally coupled to the information handling resource; and
a second heat pipe thermally coupled to the information handling resource;
wherein:
the first region includes a first part of the first heat pipe and a first part of the second heat pipe; and
the second region includes a second part of the first heat pipe and excludes the second heat pipe.
